(19) United States
(12) Patent Application Publication
(10) Pub. No.: US 2005/0168354 A1
(43) Pub. Date: Aug. 4, 2005

(54) Axis reactive perpendicular activation floating directional pad

(75) Inventors: David McVicar, El Dorado, CA (US); Richard H. Keyes McDonnell, Newark, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Logitech Europe S.A., Romanel-sur Morges (CH)

(21) Appl. No.: 10/846,467

(22) Filed: May 14, 2004

Related U.S. Application Data
(60) Provisional application No. 60/541,574, filed on Feb. 3, 2004.

(51) Int. Cl. H03M 11/00; H03K 17/94

(52) U.S. Cl. 341/20

(57) ABSTRACT

A directional pointing device produces cardinal and intercardinal directional output reliably by providing more stable axes of rotation. In some cases, the rotation is made more stable by guiding the activation of the pad in a generally perpendicular manner. In one embodiment, a directional pointing device comprises a substrate; a plurality of switches disposed on the substrate; and a cap movably coupled with the substrate to activate the switches for directional selection. The cap includes a plurality of activation features each disposed above a corresponding one of the switches to activate the corresponding switches by moving with respect to the substrate. The activation features are arranged in different radial directions with respect to a center position of the cap. Each activation feature has a width oriented generally perpendicular to the radial direction from the center position of the cap to the activation feature and a thickness oriented generally along the radial direction. The width is substantially larger than the thickness.

### CROSS-REFERENCES TO RELATED APPLICATIONS

This application is based on and claims the benefit of U.S. Provisional Patent Application No. 60/541,574, filed Feb. 3, 2004.

### BACKGROUND OF THE INVENTION

The present application relates generally to directional pads for use in a variety of devices and, more particularly, to directional pads that provide cardinal direction selection (north, south, east, west) and intercardinal direction selection (northeast, northwest, southeast, southwest).

Directional pads are used in numerous devices such as pointing devices, input devices, and other control devices to provide directional selection. Existing directional pads often produce directional output by pivoting that is unstable, and are unable to provide accurate and reliable directional output based on a user's selection, especially in the intercardinal directions.

### BRIEF SUMMARY OF THE INVENTION

The present invention relates to a directional pad that produces cardinal and intercardinal directional output reliably by providing more stable axes of rotation. In some cases, the directional selection is made more stable by guiding the activation of the pad in a generally perpendicular manner.

In accordance with an aspect of the present invention, a directional pointing device comprises a substrate; a plurality of switches disposed on the substrate; and a cap movably coupled with the substrate to activate the switches for directional selection. The cap includes a plurality of activation features each disposed above a corresponding one of the plurality of switches to activate the corresponding switches by moving with respect to the substrate. The activation features are arranged in different radial directions with respect to a center position of the cap. Each activation feature has a width oriented generally perpendicular to the radial direction from the center position of the cap to the activation feature and a thickness oriented generally along the radial direction from the center position of the cap to the activation feature. The width is substantially larger than the thickness.

In some embodiments, the cap includes four activation features being spaced substantially uniformly apart from each other by about 90° and being spaced from the center position by substantially an equal radial distance. The activation features are disposed generally on a plane. The activation features contact corresponding tops of the corresponding switches to move the switches with respect to the substrate to activate the switches.

In specific embodiments, a plurality of pistons are each disposed above one of the switches and being constrained to move generally parallel to each other. The activation features each contact a corresponding top of one of the pistons to move the pistons with respect to the substrate. A case frame having a plurality of cylindrical openings in which the pistons are disposed to guide movement of the pistons. The pistons are constrained to move in a direction generally perpendicular to the substrate. An alignment member keeps the activation features of the cap aligned with the corresponding tops of the corresponding pistons. A resilient biasing member is configured to resiliently bias the cap toward a position with the activation features disposed generally on a plane parallel to the substrate. The switches each comprise a conductive contact member having a convex surface for movably contacting the substrate and a resilient membrane connected to the conductive contact member to resiliently bias the conductive contact member away from the substrate. In other embodiments, the conductive contact member has a generally flat surface.

In accordance with another aspect of the invention, a directional pointing device comprises a substrate; a plurality of switches disposed on the substrate; a plurality of pistons each being disposed above one of the switches and being constrained to move generally parallel to each other with respect to the substrate to activate the switches; and a cap coupled with the plurality of pistons to activate the switches for directional selection. The cap includes a plurality of activation features each coupled with a corresponding one of the plurality of pistons to activate the corresponding switches by moving the pistons with respect to the substrate. The activation features are arranged in different radial directions with respect to a center position of the cap.

In accordance with another aspect of the present invention, a directional pointing device comprises a substrate; a plurality of switches each having a contact member movable between a contact position to contact the substrate and a noncontact position to be spaced from the substrate; and a cap movable with respect to the substrate to activate the switches for directional selection. The cap includes a plurality of activation features each corresponding to one of the plurality of switches to activate the corresponding switch by moving the switch with respect to the substrate. The activation features are arranged in different radial directions with respect to a center position of the cap. The device further comprises a mechanism coupled with the cap and the switches for moving one or more of the switches between the contact position and the noncontact position in a direction generally perpendicular to the substrate in response to movement of the cap for directional selection.

### BRIEF DESCRIPTION OF THE DRAWINGS

FIG. 1 is a perspective view with partial cross sections illustrating a directional pad according to one embodiment of the present invention.

FIG. 2 is an exploded perspective view of the directional pad of FIG. 1.

FIG. 3 is a perspective view of the directional pad of FIG. 1 illustrating cardinal directional selections.

FIG. 4 is a perspective view of the directional pad of FIG. 1 illustrating intercardinal directional selections.

FIG. 5 is a perspective view of the directional pad of FIG. 1 illustrating a specific cardinal directional selection.

FIG. 6 is a perspective view of the directional pad of FIG. 5 with partial cut-out to illustrate the interior components.

FIG. 7 is a perspective view of a cap showing in cutaway the activation feature arrangement and location of the directional pad of FIG. 6.

FIG. 8 is another perspective view of the directional pad of FIG. 6 illustrating the rotational characteristics thereof.

FIG. 9 is an elevational view of the directional pad of FIG. 6 illustrating the rotational characteristics thereof.

FIG. 10 is another elevational view of the directional pad of FIG. 6 illustrating buckling of the switch membrane according to one embodiment of the invention.

FIG. 11 is a plot of force versus travel for the buckling of the switch membrane.

FIG. 12 is a cross-sectional view of a switch according to one embodiment of the invention.

FIG. 13 is a partial cross-sectional view of a switch in the directional pad of FIG. 1 illustrating perpendicular activation thereof.

FIG. 14 is a partial cross-sectional view of a switch in an existing directional pad.

FIG. 15 is a plot of force versus travel comparing the buckling of the switch in the existing directional pad of FIG. 14 and the switch in the directional pad of FIG. 1.

FIG. 16 is another partial cross-sectional view of the switch of FIG. 14.

FIG. 17 is a perspective view with partial cut-out of the directional pad of FIG. 14.

FIG. 18 is a perspective view of the directional pad of FIG. 1 illustrating a specific intercardinal directional selection.

FIG. 19 is a perspective view of the directional pad of FIG. 18 with partial cut-out to illustrate the interior components.

FIG. 20 is another perspective view of the directional pad of FIG. 18 illustrating the rotational characteristics thereof.

FIG. 21 is an elevational view of the directional pad of FIG. 18 illustrating the rotational characteristics thereof.

FIG. 22 is an exploded perspective view of a directional pad according to another embodiment of the present invention.

FIG. 23 is a perspective view with partial cut-out of the directional pad of FIG. 22 illustrating the rotational characteristics thereof.

FIG. 24 is an elevational view of the directional pad of FIG. 22 illustrating the rotational characteristics thereof.

### DETAILED DESCRIPTION OF THE INVENTION

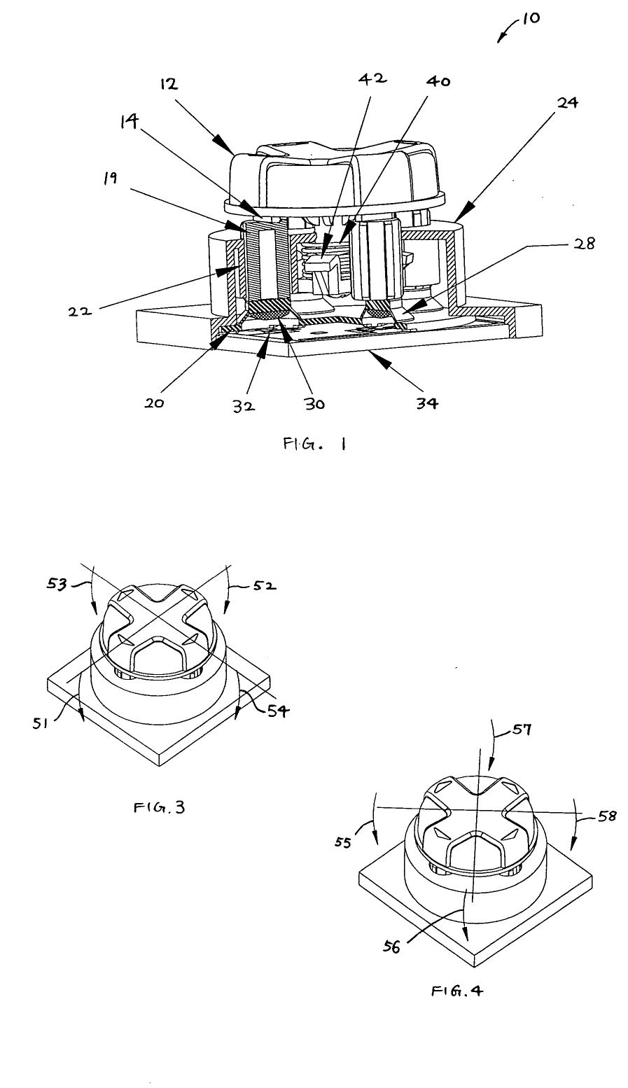

As shown in FIGS. 1 and 2, a directional pad (D-pad) 10 includes a cap 12 which has four activation features 14 located generally in a plane and at the four cardinal directions (north, south, east, and west). The activation features 14 are arranged in different radial directions with respect to a center position of the cap 12, and are spaced from the center position by substantially an equal distance. These four features are in contact with the tops 18 of four piston actuators 19 which provide hard surfaces at the top of the pistons 19. The pistons 19 are constrained to vertical movement, perpendicular to the keymat 20 by cylinders or cylindrical openings 22 located in a case frame 24. As seen in FIG. 2, the keymat switches 26 are located at the four cardinal directions, and aligned with the four cylinders 22 and four corresponding pistons 19. The keymat switches 26 each include a silicone cylindrical webbed membrane 28 with a conductive “pill” or member 30 at the center thereof. These conductive pills 30 are aligned to trace contact areas 32 located on a substrate or printed circuit board (PCB) 34. Each conductive pill 30 is movable between a contact position to contact the PCB 34 and a noncontact position to be spaced from the PCB 34. The membrane 28 resiliently biases the conductive pill 30 away from the PCB 34. The D-pad cap 12 is desirably held to the tops of the pistons 19, for instance, with a resilient member in the form of a spring 40. The spring 40 preferably generates enough force to hold the cap 12 in contact with the pistons 19, but not enough to depress the keymat switches 26. The spring 40 is constrained by a cap alignment member or alignment stopper 42, which keeps the cap's four activation features 14 aligned with the four piston tops using four alignment arms 44 that fit into ribbed spaces in the case frame 24. The activation features 14 of the cap 12 are resiliently biased to lie generally on a plane parallel to the PCB 34. A screw 48 attaches the cap alignment stopper 42 to the cap 12 with the spring 40 sandwiching the case frame 24 therebetween.

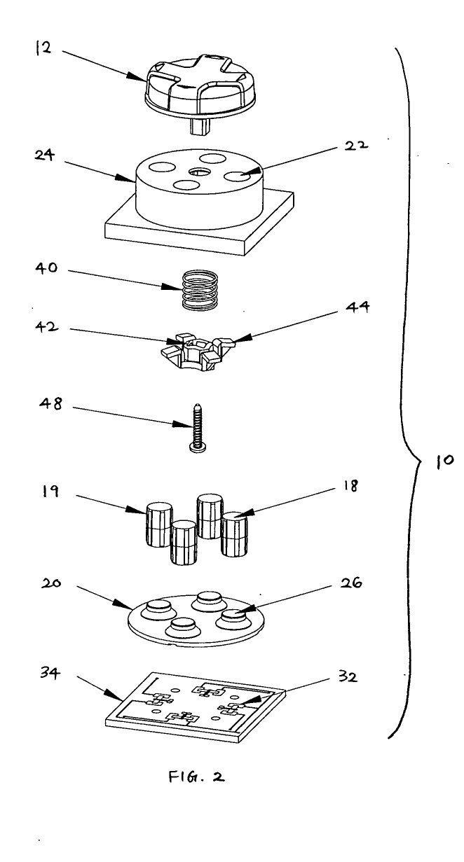

The D-pad 10 functions by instantly creating an axis of rotation when reacting to the pressure created by the user in selecting a direction. There are commonly eight directions that can be selected, including four cardinal directions (north 51, south 52, east 53, west 54) as shown in FIG. 3 and four intercardinal directions (northeast 55, northwest 56, southeast 57, southwest 58).

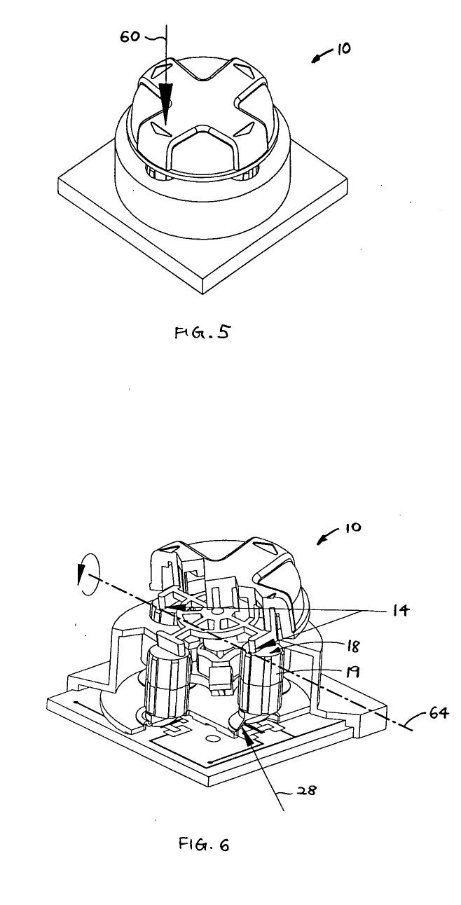

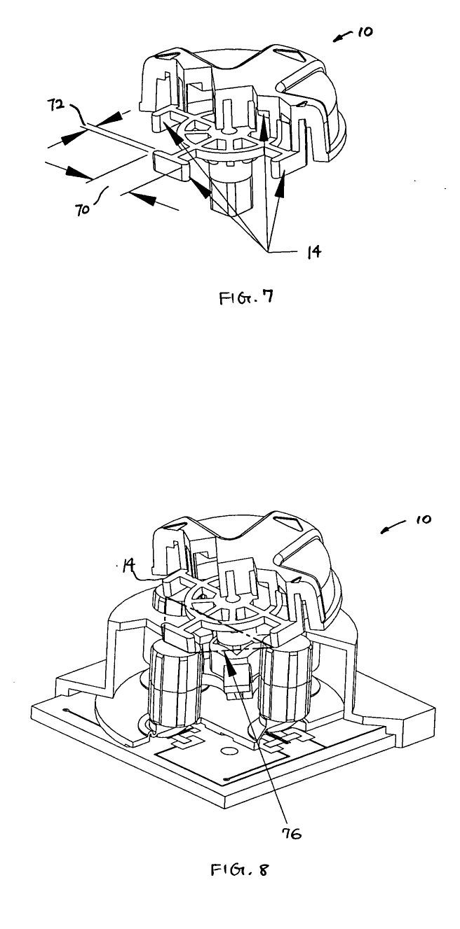

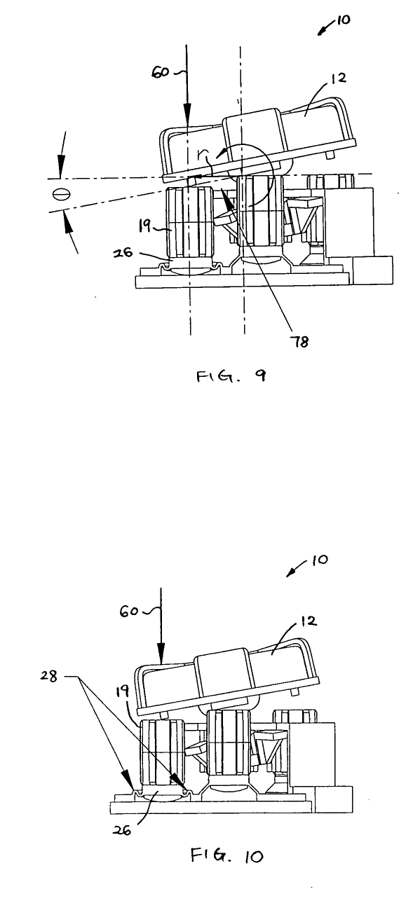

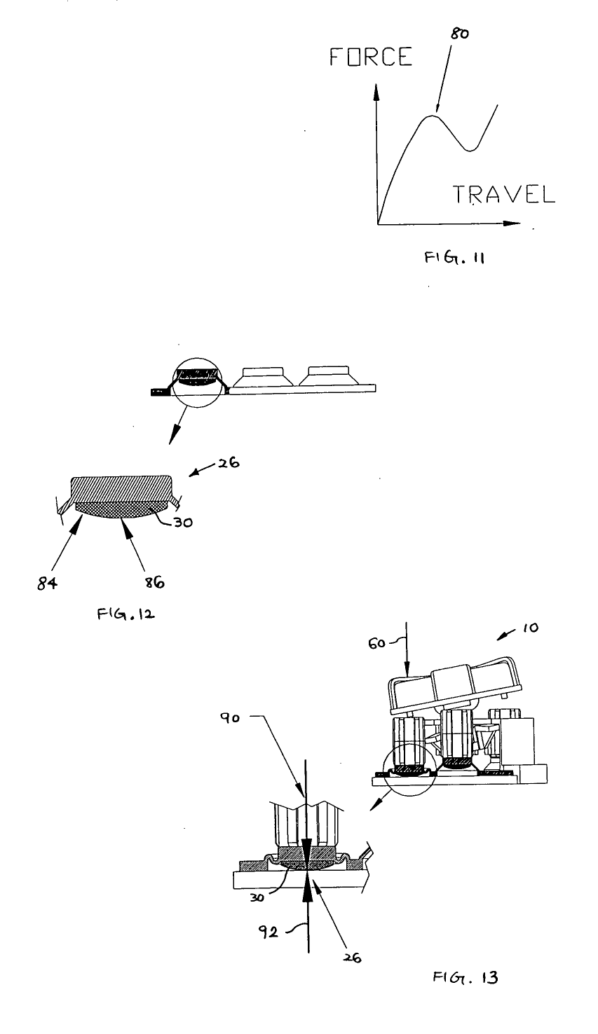

The first type of axis creation is cardinal direction selection. When the user wants to select a cardinal direction (e.g., “north”), he or she presses the “north” position on the D-pad cap 12 toward and above the north switch and piston, as illustrated by the arrow 60 in FIG. 5. FIG. 6 shows various parts of the D-pad 10 in a cutaway view to illustrate the internal features. At this time there are three interactions that occur to provide a very stable and “directionally” intuitive feedback to the user ensuring only “north” is selected. First, the leading corners of the east and west activation features 14 create an axis of rotation 64 caused by the resistance to vertical movement of each of these two locations created by the east and west switch membranes 28. They rotate on the solid platforms created by, and in the plane of, the hard piston tops 18 of the east and west pistons 16. This causes a resistance to tipping either to the left (east) or to the right (west), thereby limiting accidental selection of a neighboring intercardinal direction (northeast or north west). This reactive axis does not carry the full load or torque of switch activation. What it does is to carry a portion of the load of the switch activation to create a stabilizing effect. Second, as seen in FIG. 7, the cap activation features 14 each have a large width “side to side” 70, and a narrow dimension or thickness 72 in the direction of tipping, further stabilizing the D-pad cap 12 from tilting to the sides. The width 70 is substantially larger than the thickness 72, and is typically at least about twice, more desirably at least about four times, as large as the thickness 72. These two features work together to produce an isosceles trapezoid 76 in the direction of D-pad cap rotation 76, as seen in FIG. 8. As shown in the region 78 of FIG. 9, the cap 12 floats on top of the pistons 19. The moment arm is the distance from the leading edge of the activation feature 14 to the axis of rotation 64, defined here as the radius “r.” The angle that the cap 12 tips through is θ. The third unique feature of this configuration results from the perpendicular action of the piston 19 on the switch 26. Since the force is applied evenly to the entire top of the switch 26, the buckling action of the switch membrane 28 is uniform and consistent, as illustrated in FIG. 10, and at its highest value 80, as shown in FIG. 11. This buckling point 80 provides the user with the distinctive “click” that produces the tactile feedback indicating that the correct switch was activated. Some D-pads use conductive pills 30 that have a convex surface such as a cone-shaped surface 84 with a small flat tip 86, as seen in FIG. 12. These “analog progressive” switches change their output as a function of the amount of deformation of the conductive pill due to variations of the applied force. On the piston design, this conductive pill is moved perpendicularly to the trace, as illustrated by the arrow 90 in FIG. 13, thereby resulting in consistent placement and deformation of the pill point at the center 92 of the trace. In alternative embodiments, the conductive pill 30 has a generally flat surface for contacting the PCB 108, for example, in a digital switch.

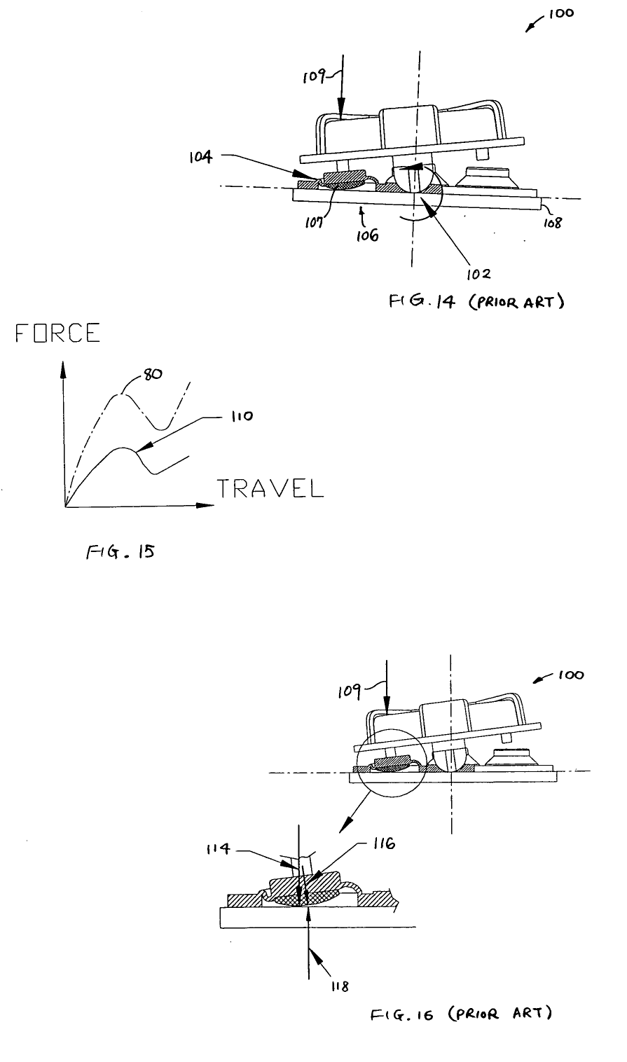

FIG. 14 shows a currently available D-pad 100, which generally relies on a central pivot point 102 to provide the directional bias. While this pivot point may come in various forms and at various points relative to the switch top plan of action, it always relies on a tipping movement that results in the switch membrane web 104 of the switch 106 being deformed at an angle. The conductive pill 107 makes an off-center contact with the PCB 108 under a force along a line 109. This asymmetric application of force causes early buckling on one side that results in a lower buckling force 110 as compared to the buckling point 80 in FIG. 11, creating a smaller tactile feedback to the user, as illustrated in FIG. 15. A second consequence of this angled depression of the switch 106 is that the contact point of the conductive pill 107 is altered and its alignment to the trace altered. As seen in FIG. 16, the resultant contact point 114 is shifted from the center or intended contact point 116 of the conductive pill 107, and away from the center 118 of the trace on the printed circuit board. In the tipping configuration, the pill point or center of the conductive pill 107 does not touch the board first and the deformation is not equal on all sides of the trace, resulting in erratic progressive output. This also leads to “scuffing” of the trace and pill due to a small component of the applied force acting in the radial direction. A third consequence of the pivot approach to D-pad operation is that the moment arm that exists between the pivot point of contact 120 and the top of the keymat switch 106 creates a triangle 124 with a very small base that is located in a plane perpendicular to the plane of the switch tops, as illustrated in FIG. 17. This results in a rather unstable application of force to the top of the switch 106 without any exterior forces available to prevent the activation of another switch to the left or the right of the intended switch.

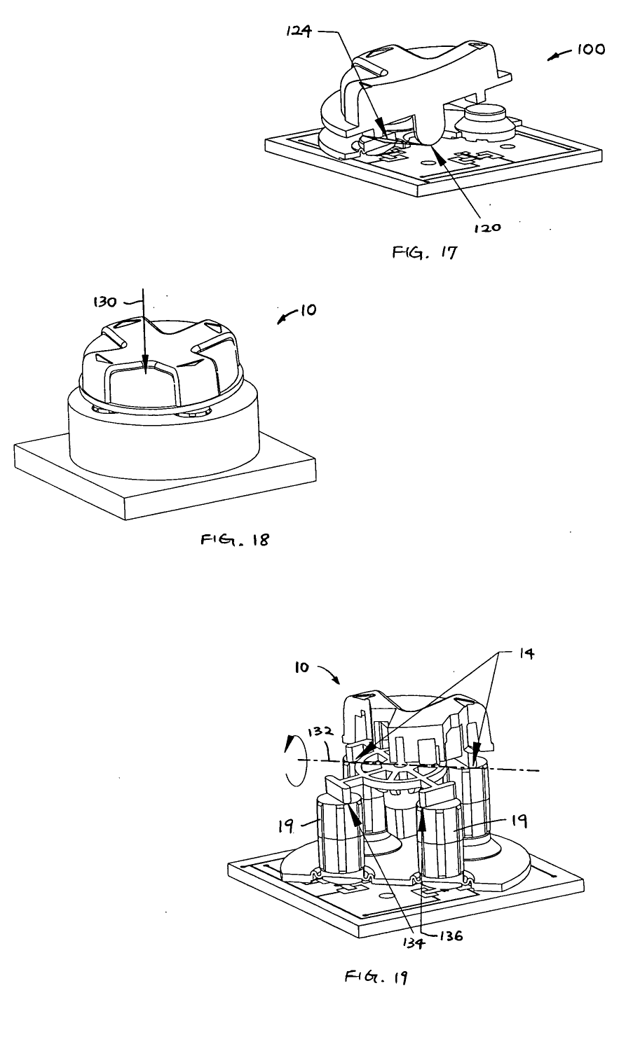

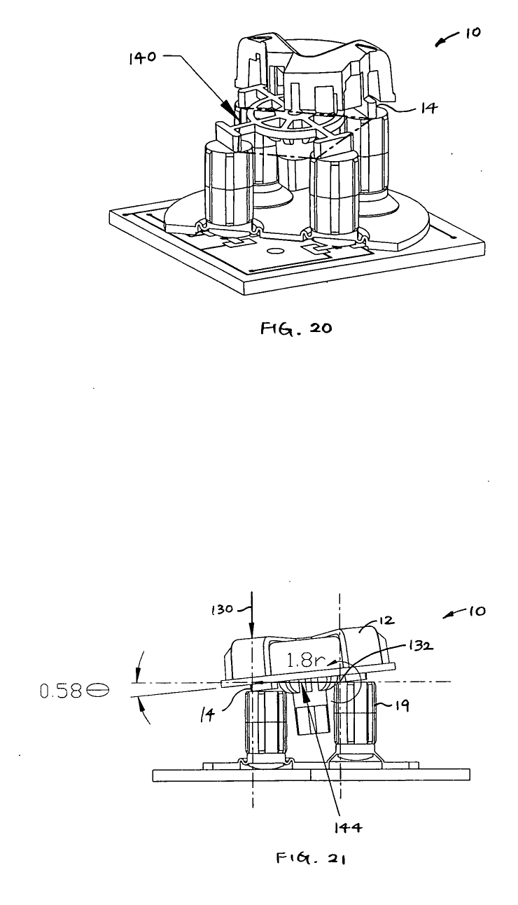

The second type of axis creation is intercardinal direction selection. When the user wants to select an intercardinal direction (e.g., “northwest”), the force is applied between the north and west positions on the D-pad Cap 12, as illustrated by the arrow 130 in FIG. 18. Once again, there are three interactions that occur to provide a stable and “directionally” intuitive feedback to the user, thereby promoting the selection of the “northwest” direction. First, the outside, front corners of the east and south activation features 14 create an axis of rotation 132 caused by the resistance to vertical movement of each of these points as generated by the east and south switch membranes. They rotate on the solid platforms created by, and in the plane of, the hard piston tops. This causes a resistance to tipping either to the left (north) or to the right (west), thereby resisting accidental selection of a neighboring cardinal direction. Second, the forward inside corners 134, 138 of the cap activation features for north and west are disposed at a large distance from each other, creating a stable platform between these two points relative to the tops of the north and west pistons 19, further stabilizing the D-pad cap 12 from tilting to the sides. These two features work together to produce an isosceles trapezoid 140 in the direction of D-pad cap rotation, as shown in FIG. 20. As illustrated in the region 144 of FIG. 21, the cap 12 floats on top of the pistons 19. The moment arm is the distance from the corner of the activation feature 14 to the axis of rotation, defined here as the radius “1.8r.”. This moment arm is longer than the cardinal moment arm resulting in a smaller angle of rotation of about 0.58 θ as compared to the rotation in the cardinal direction of FIG. 9. As noted before, this axis of rotation 132 does not carry the full load or torque at this axis. It acts only to provide a stabilizing effect. The third unique feature of this design results from the perpendicular action of the pistons 19 on the switches 26. Since the force is applied evenly to the entire top of each switch 26, the buckling action of each switch membrane 28 is uniform, consistent, and at its highest value (see FIGS. 10 and 11). Because two switches are being depressed at one time in the intercardinal direction, the user feels a higher resistance to operation, and since the moment arm is longer, the angle that the D-pad cap 12 tips through is smaller providing yet another form of tactile feed back to the user. Therefore, the buckling point for the intercardinal direction provides the user with a distinctive “click” which is different from the cardinal “click,” thereby providing a different tactile feedback to inform the user that the correct switch is activated.

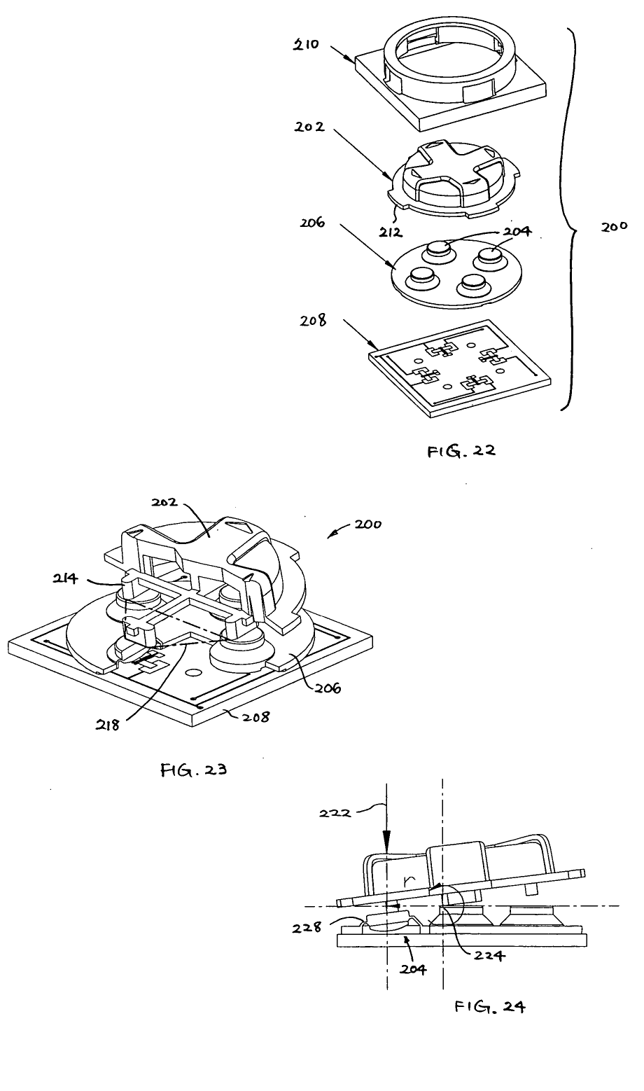

FIGS. 22-24 show another D-pad 200 that has a simpler structure and is less costly to manufacture. The cost structure of some products that utilize a D-pad can make the piston activation feature in the D-pad 10 of FIGS. 1-13 and 18-21 too expensive. In these situations, a reduced cost version such as the D-pad 200 shown in FIGS. 22-24 is possible by removing the pistons and floating the D-pad cap 202 directly over the tops of the keymat switches 204 on the keymat 206. The keymat 206 is disposed over traces on a PCB 208. A retaining member 210 is placed over the assembly to hold the components of the D-pad 200 together. The retaining member 210 places an upper constraint of movement on the four tabs 212 of the cap 202, which maintains alignment of the cap 202. This D-pad 200 does not produce the vertical displacement in the D-pad 10, but is able to generate substantial stability in the directional selection. For instance, the activation features 214 are similar to the activation features 14 in the D-pad 10. As seen in FIG. 23, the activation features 214 of the D-pad 200 produce an isosceles trapezoid 218 in the direction of the D-pad cap rotation similar to that shown in FIG. 8 for the D-pad 10. As illustrated in FIG. 24, the moment arm is the distance from the line of application of the force 222 to the axis of rotation 224, defined here as the radius “r.” There is a slight nonuniform buckling of the switch membrane 228 of the switch 204, but the buckling is more uniform than that in existing D-pads. Since there is no pivot point as in existing D-pads, most of the benefits of the floating actuator are available in this embodiment of the D-pad 200. Operation in the cardinal, and inter-cardinal directions create generally the same active axis and planar tetrahedron as in the piston configuration of the D-pad 10. Because the switches 204 in the simplified D-pad 200 operate at an angle, there is a decrease of accuracy. Experiments show that the accuracy of the D-pad 10 (FIGS. 1-13 and 18-21) is about 95% or higher and the accuracy of the simplified D-pad 200 (FIGS. 22-24) is about 90%, which represent significant improvement over existing D-pads such as the D-pad 100 (FIGS. 14-17) at an accuracy of about 80% or lower.

It is to be understood that the above description is intended to be illustrative and not restrictive. Many embodiments will be apparent to those of skill in the art upon reviewing the above description. The scope of the invention should, therefore, be determined not with reference to the above description, but instead should be determined with reference to the appended claims along with their full scope of equivalents.

1. A directional pointing device comprising:
a substrate;
a plurality of switches disposed on the substrate; and
a cap movably coupled with the substrate to activate the switches for directional selection, the cap including a plurality of activation features each disposed above a corresponding one of the plurality of switches to activate the corresponding switches by moving with respect to the substrate, the activation features being arranged in different radial directions with respect to a center position of the cap, each activation feature having a width oriented generally perpendicular to the radial direction from the center position of the cap to the activation feature and a thickness oriented generally along the radial direction from the center position of the cap to the activation feature, the width being substantially larger than the thickness.

2. The device of claim 1 wherein the cap includes four activation features being spaced substantially uniformly apart from each other by about 90° and being spaced from the center position by substantially an equal radial distance.

3. The device of claim 1 wherein the activation features are disposed generally on a plane.

4. The device of claim 3 wherein the activation features contact corresponding tops of the corresponding switches to move the switches with respect to the substrate to activate the switches.

5. The device of claim 3 further comprising a plurality of pistons each being disposed above one of the switches and being constrained to move generally parallel to each other, and wherein the activation features each contact a corresponding top of one of the pistons to move the pistons with respect to the substrate.

6. The device of claim 5 further comprising a case frame having a plurality of cylindrical openings in which the pistons are disposed to guide movement of the pistons.

7. The device of claim 5 wherein the pistons are constrained to move in a direction generally perpendicular to the substrate.

8. The device of claim 5 further comprising an alignment member to keep the activation features of the cap aligned with the corresponding tops of the corresponding pistons.

9. The device of claim 3 further comprising a resilient biasing member configured to resiliently bias the cap toward a position with the activation features disposed generally on a plane parallel to the substrate.

10. The device of claim 1 wherein the switches each comprise a conductive contact member having a convex surface for movably contacting the substrate and a resilient membrane connected to the conductive contact member to resiliently bias the conductive contact member away from the substrate.

11. A directional pointing device comprising:
a substrate;
a plurality of switches disposed on the substrate;
a plurality of pistons each being disposed above one of the switches and being constrained to move generally parallel to each other with respect to the substrate to activate the switches; and
a cap coupled with the plurality of pistons to activate the switches for directional selection, the cap including a plurality of activation features each coupled with a corresponding one of the plurality of pistons to activate the corresponding switches by moving the pistons with respect to the substrate, the activation features being arranged in different radial directions with respect to a center position of the cap.

12. The device of claim 11 further comprising a case frame having a plurality of cylindrical openings in which the pistons are disposed to guide movement of the pistons with respect to the substrate.

13. The device of claim 11 wherein the pistons are constrained to move in a direction generally perpendicular to the substrate.

14. The device of claim 11 further comprising an alignment member to keep the activation features of the cap aligned with the corresponding pistons.

15. The device of claim 11 wherein the activation features are disposed generally on a plane.

16. The device of claim 11 wherein each activation feature has a width oriented generally perpendicular to the radial direction from the center position of the cap to the activation feature and a thickness oriented generally along the radial direction from the center position of the cap to the activation feature, the width being substantially larger than the thickness.

17. The device of claim 11 wherein the switches each comprise a conductive contact member having a convex surface for movably contacting the substrate and a resilient membrane connected to the conductive contact member to resiliently bias the conductive contact member away from the substrate.

18. A directional pointing device comprising:
a substrate;
a plurality of switches each having a contact member movable between a contact position to contact the substrate and a noncontact position to be spaced from the substrate;
a cap movable with respect to the substrate to activate the switches for directional selection, the cap including a plurality of activation features each corresponding to one of the plurality of switches to activate the corresponding switch by moving the switch with respect to the substrate, the activation features being arranged in different radial directions with respect to a center position of the cap; and
means coupled with the cap and the switches for moving one or more of the switches between the contact position and the noncontact position in a direction generally perpendicular to the substrate in response to movement of the cap for directional selection.

19. The device of claim 18 wherein the cap includes four activation features being spaced substantially uniformly apart from each other by about 90° and being spaced from the center position by substantially an equal radial distance.

20. The device of claim 18 wherein each activation feature has a width oriented generally perpendicular to the radial direction from the center position of the cap to the activation feature and a thickness oriented generally along the radial direction from the center position of the cap to the activation feature, the width being substantially larger than the thickness.

21. The device of claim 18 wherein the activation features are disposed generally on a plane.

22. The device of claim 18 wherein the switches each comprise a conductive contact member having a convex surface for movably contacting the substrate and a resilient membrane connected to the conductive contact member to resiliently bias the conductive contact member away from the substrate.

23. The device of claim 18 wherein the switches each comprise a conductive contact member having a generally flat surface for movably contacting the substrate and a resilient membrane connected to the conductive contact member to resiliently bias the conductive contact member away from the substrate.
